(19) United States
(12) Patent Application Publication
(10) Pub. No.: US 2015/0213850 A1
(43) Pub. Date: Jul. 30, 2015

(54) SERIAL DATA TRANSMISSION FOR DYNAMIC RANDOM ACCESS MEMORY (DRAM) INTERFACES

(71) Applicant: QUALCOMM Incorporated, San Diego, CA (US)

(72) Inventors: Vaishnav Srinivas, San Diego, CA (US); Michael Joseph Brunolli, Escondido, CA (US); Dexter Tamio Chun, San Diego, CA (US); David Ian West, San Diego, CA (US)

(21) Appl. No.: 14/599,768

(22) Filed: Jan. 19, 2015

Related U.S. Application Data
(60) Provisional application No. 61/930,985, filed on Jan. 24, 2014.

(51) Int. Cl. G11C 7/10

(52) U.S. Cl. CPC G11C 7/1072

(57) ABSTRACT

Serial data transmission for dynamic random access memory (DRAM) interfaces is disclosed. Instead of the parallel data transmission that gives rise to skew concerns, exemplary aspects of the present disclosure transmit the bits of a word serially over a single lane of the bus. Because the bus is a high speed bus, even though the bits come in one after another (i.e., serially), the time between arrival of the first bit and arrival of the last bit of the word is still relatively short. Likewise, because the bits arrive serially, skew between bits becomes irrelevant. The bits are aggregated within a given amount of time and loaded into the memory array.

### PRIORITY CLAIM

The present application claims priority to U.S. Provisional Patent Application Ser. No. 61/930,985 filed on Jan. 24, 2014 and entitled “SERIAL DATA TRANSMISSION FOR A DYNAMIC RANDOM ACCESS MEMORY (DRAM) INTERFACE,” which is incorporated herein by reference in its entirety.

### BACKGROUND

I. Field of the Disclosure

The technology of the disclosure relates generally to memory structures and data transfer therefrom.

II. Background

Computing devices rely on memory. The memory may be a hard drive or removable memory drive, for example, and may store software that enables functions on the computing device. Further, memory allows software to read and write data that is used in execution of the software's functionality. While there are several types of memory, random access memory (RAM) is among the most frequently used by computing devices. Dynamic RAM (DRAM) is one type of RAM that is used extensively. Computation speed is at least partially a function of how fast data can be read from the DRAM cells and how fast data can be written to the DRAM cells. Various topologies have been formulated for coupling DRAM cells to an applications processor through a bus. One popular format of DRAM is double data rate (DDR) DRAM. In release 2 of the DDR standard (i.e., DDR2) a T-branch topology was used. In release 3 of the DDR standard (i.e., DDR3), a fly-by topology was used.

In existing DRAM interfaces, data is sent in a parallel manner across the width of the bus. That is, for example, eight bits of an eight-bit word are all sent at the same instance across eight lanes of the bus. The bits are captured in the memory, aggregated into a block, and uploaded into a memory array. When such a parallel transmission is used, especially in a fly-by topology, the word has to be synchronously captured so that the memory may identify the bits as belonging to the same word and upload the bits to the correct memory address.

Skew between bits and between lanes of the bus is unavoidable, and becomes truly problematic at higher speeds. This skew in timing can be “leveled” by adjusting, through training, the delays of the bits and strobes. This “leveled” approach is frequently referred to as “write-leveling.” Write leveling is a hard problem to solve at high speeds and requires an adjustable clock, which in turn leads to complicated frequency switching issues. Thus, there is a need for an improved manner of transferring data to the DRAM arrays.

### SUMMARY OF THE DISCLOSURE

Aspects disclosed in the detailed description include serial data transmission for dynamic random access memory (DRAM) interfaces. Instead of the parallel data transmission that gives rise to skew concerns, exemplary aspects of the present disclosure transmit the bits of a word serially over a single lane of the bus. Because the bus is a high speed bus, even though the bits come in one after another (i.e., serially), the time between arrival of the first bit and arrival of the last bit of the word is still relatively short. Likewise, because the bits arrive serially, skew between bits becomes irrelevant. The bits are aggregated within a given amount of time and loaded into the memory array.

By sending the bits serially, the need to perform write leveling is eliminated, which reduces training time and area overhead within the memory device. Likewise, power saving techniques may be implemented by turning off lanes that are not needed. Once selective lane activation is used, transmission rates may be varied without having to change the clock frequency. This bandwidth adjustment can be accomplished much faster than with frequency scaling because there is no need to wait for a lock by a phase locked loop (PLL) or training of the channel.

In this regard, in an exemplary aspect, a method is disclosed. The method comprises serializing a byte of data at an applications processor (AP). The method also comprises transmitting the serialized byte of data across a single lane of a bus to a DRAM element. The method also comprises receiving, at the DRAM element, the serialized byte of data from the single lane of the bus.

In this regard, in another exemplary aspect, a memory system is disclosed. The memory system comprises a communication bus comprising a plurality of data lanes and a command lane. The memory system also comprises an AP. The AP comprises a serializer. The AP also comprises a bus interface operatively coupled to the communication bus. The AP also comprises a control system. The control system is configured to cause the serializer to serialize a byte of data and pass the serialized byte of data through the bus interface to the communication bus. The memory system also comprises a DRAM element. The DRAM element comprises a DRAM bus interface operatively coupled to the communication bus. The DRAM element also comprises a deserializer configured to receive data from the DRAM bus interface and deserialize the received data. The DRAM element also comprises a memory array configured to store data received by the DRAM element.

In this regard, in another exemplary aspect, an AP is disclosed. The AP comprises a serializer. The AP also comprises a bus interface operatively coupled to a communication bus. The AP also comprises a control system. The control system is configured to cause the serializer to serialize a byte of data and pass the serialized byte of data through the bus interface to a single lane of the communication bus.

In this regard, in another exemplary aspect, a DRAM element is disclosed. The DRAM element comprises a DRAM bus interface operatively coupled to a communication bus. The DRAM element also comprises a deserializer configured to receive data from the DRAM bus interface and deserialize the received data. The DRAM element also comprises a memory array configured to store data received by the DRAM element.

### BRIEF DESCRIPTION OF THE FIGURES

FIG. 1 is a block diagram of an exemplary conventional parallel data transfer;

FIG. 2 is a block diagram of an exemplary aspect of a memory system with serial data transfer capabilities;

FIG. 3 is a block diagram of a dynamic random access memory (DRAM) element of FIG. 2 with an exemplary deserializer to receive serial data;

FIG. 4 is a block diagram of the memory system of FIG. 2 with bandwidth and power scaling accomplished by using serial data transfer and selective lane activation;

FIG. 5 is a flow chart illustrating an exemplary process associated with the memory system of FIG. 2; and

FIG. 6 is a block diagram of an exemplary processor-based system that can include the memory system of FIG. 2.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include serial data transmission for dynamic random access memory (DRAM) interfaces. Instead of the parallel data transmission that gives rise to skew concerns, exemplary aspects of the present disclosure transmit the bits of a word serially over a single lane of the bus. Because the bus is a high speed bus, even though the bits come in one after another (i.e., serially), the time between arrival of the first bit and arrival of the last bit of the word is still relatively short. Likewise, because the bits arrive serially, skew between bits becomes irrelevant. The bits are aggregated within a given amount of time and loaded into the memory array.

By sending the bits serially, the need to perform write leveling is eliminated, which reduces training time and area overhead within the memory device. Likewise, power saving techniques may be implemented by turning off lanes that are not needed. Once selective lane activation is used, transmission rates may be varied without having to change the clock frequency. This bandwidth adjustment can be accomplished much faster than with frequency scaling because there is no need to wait for a lock by a phase locked loop (PLL) or training of the channel.

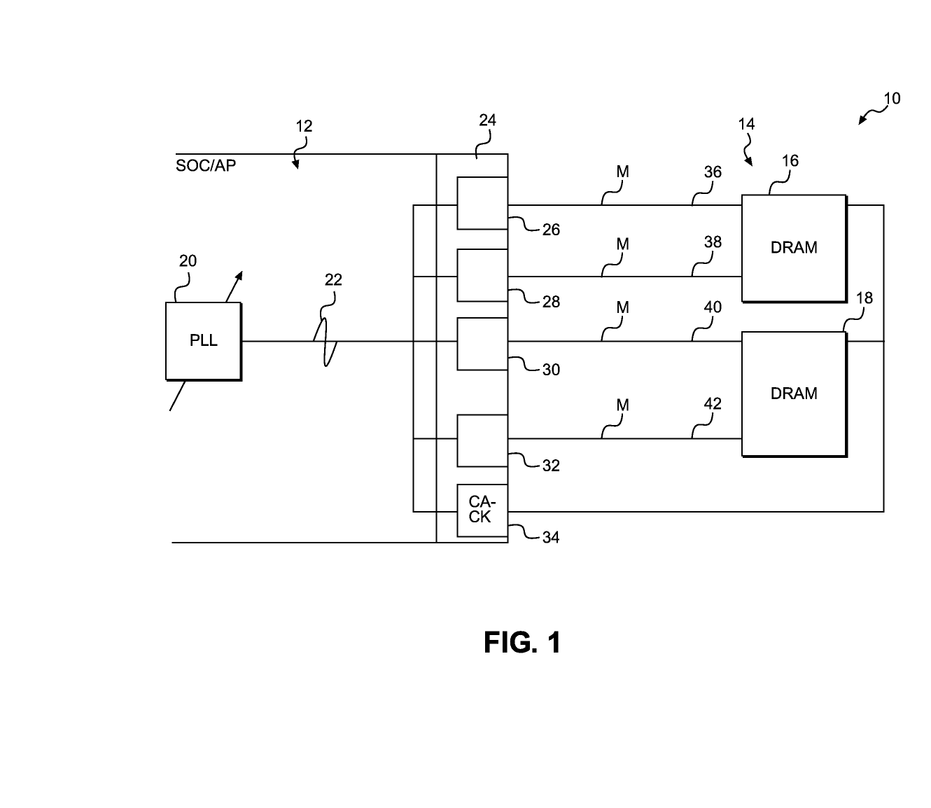

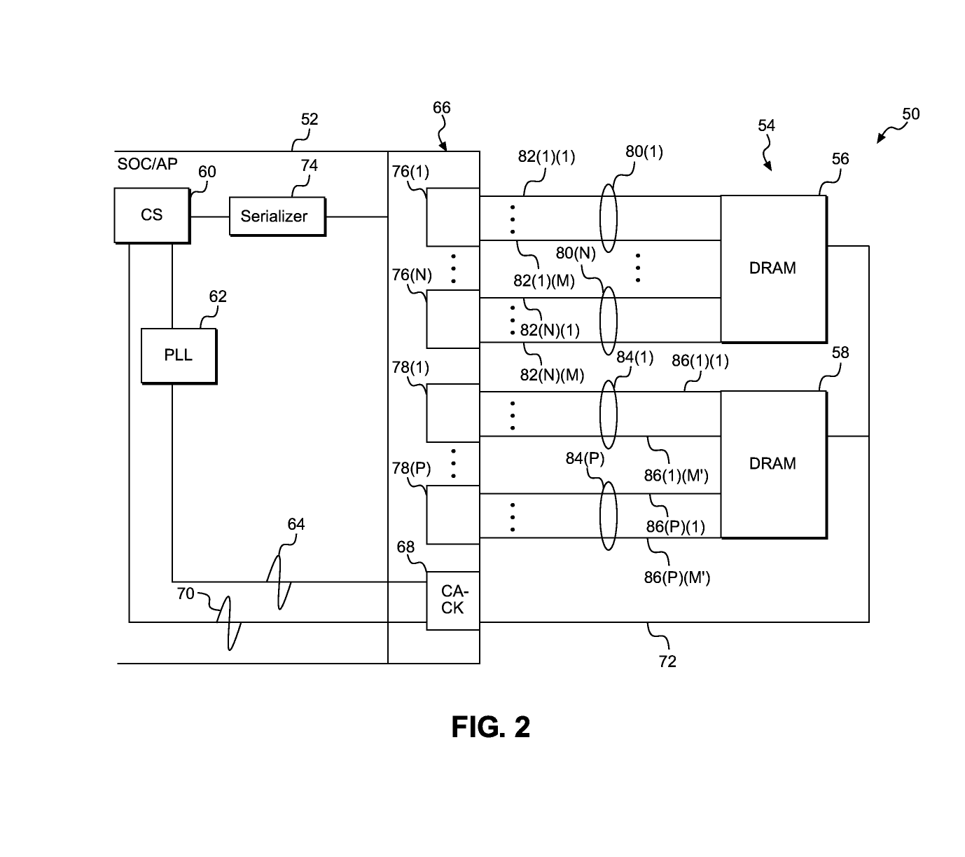

Before addressing exemplary aspects of the present disclosure, a brief review of a conventional parallel data transfer scheme is provided with reference to FIG. 1. The discussion of exemplary aspects of a serial data transfer scheme begins below with reference to FIG. 2. In this regard, FIG. 1 is a conventional memory system 10 with a system on chip (SoC) 12 (sometimes referred to as an applications processor (AP)) and a bank 14 of DRAM elements 16 and 18. The SoC 12 includes a variable frequency PLL 20, which provides a clock (CK) signal 22. The SoC 12 also includes an interface 24. The interface 24 may include bus interfaces 26, 28, 30, and 32, as well as CA-CK interface 34.

With continuing reference to FIG. 1, each bus interface 26, 28, 30, and 32 may couple to a respective M lane bus 36, 38, 40, and 42 (where M is an integer greater than one (1)). M lane buses 36 and 38 may couple the SoC 12 to the DRAM element 16, while M lane buses 40 and 42 may couple the SoC 12 to the DRAM element 18. In an exemplary aspect, the M lane buses 36, 38, 40, and 42 are each eight (8) lane buses. The SoC 12 may generate command and address (CA) signals, which are passed to the CA-CK interface 34. Such CA signals and the clock signal 22 are shared with the DRAM elements 16 and 18 through a fly-by topology.

With continued reference to FIG. 1, a word is generated within the SoC 12, for example, a 32-bit word, comprised of four (4) bytes of data (eight (8) bits each), which is divided among the four bus interfaces 26, 28, 30, and 32. In the conventional parallel transmission technique, all four bytes have to reach the DRAM elements 16 and 18 at the same time relative to the clock signal 22. Because the clock signal 22 arrives at the DRAM elements 16 and 18 at different times by virtue of the fly-by topology, the transmissions from the four bus interfaces 26, 28, 30, and 32 are controlled through a complex write-leveling process. The variable PLL 20 frequency is the only way to reduce or scale bandwidth and power for such parallel transmissions.

To eliminate the disadvantages imposed by write leveling and to eliminate the need for the variable PLL 20, exemplary aspects of the present disclosure provide for serial transmission of the words over single lanes within the data bus. Since the words are received serially, there is no need for the precise timing or write leveling of the memory system 10. Further, by serializing the data and sending words on single lanes within the data bus, the effective bandwidth may be throttled by choosing which lanes are operational.

In this regard, FIG. 2 illustrates a memory system 50 with a SoC 52 (also referred to as an AP) and a bank 54 of DRAM elements 56 and 58. The SoC 52 includes a control system (CS) 60 and a PLL 62. The PLL 62 generates a clock (CK) signal 64. The SoC 52 also includes an interface 66. The interface 66 may include a CA-CK interface 68. The control system 60 may provide command and address (CA) signals 70 to the CA-CK interface 68 with the clock signal 64. The CA-CK interface 68 may couple to a communication lane 72 that is arranged in a fly-by topology for communication with the DRAM elements 56 and 58. The SoC 52 may further include one or more serializers 74 (only one shown). The interface 66 may include bus interfaces 76(1)-76(N) and 78(1)-78(P) (where N and P are integers greater than one (1)). The bus interfaces 76(1)-76(N) couple to respective M lane buses 80(1)-80(N) (where M is an integer greater than one (1)). Each of the M lane buses 80(1)-80(N) includes respective data lanes 82(1)(1)-82(1)(M) through 82(N)(1)-82(N)(M). The data lanes 82(1)(1)-82(1)(M) through 82(N)(1)-82(N)(M) connect the SoC 52 to the DRAM element 56. Similarly, the bus interfaces 78(1)-78(P) couple to respective M′ lane buses 84(1)-84(P) (where M′ is an integer greater than one (1)). Each of the M′ lane buses 84(1)-84(P) includes respective data lanes 86(1)(1)-86(1)(M′) through 86(P)(1)-86(P)(M′). In an exemplary aspect, N=P=2 and M=M′=8. The data lanes 86(1)(1)-86(1)(M′) through 86(P)(1)-86(P)(M′) connect the SoC 52 to the DRAM element 58. In an exemplary aspect, there are serializers 74 equal to the number of lanes coupled to the interface 66 (excluding the communication lane 72) (e.g., N plus P). In another exemplary aspect, a multiplexer (not illustrated) routes output of a single serializer 74 to each lane coupled to the interface 66 (again excluding the communication lane 72).

With continued reference to FIG. 2, in the memory system 50, a word being sent to the DRAM element 56 is sent only on a single data lane 82 of the M lane bus 80 (e.g., data lane 82(1)(1) of M lane bus 80(1)). Thus, for example, if the word is 32 bits, with four bytes, each bit of each byte is sent on a single data lane 82 of the M lane bus 80. Different words are stored in different ones of the DRAM elements 56 and 58. While only two DRAM elements 56 and 58 are illustrated, it should be appreciated that alternate aspects may have more DRAM elements with corresponding multilane data buses.

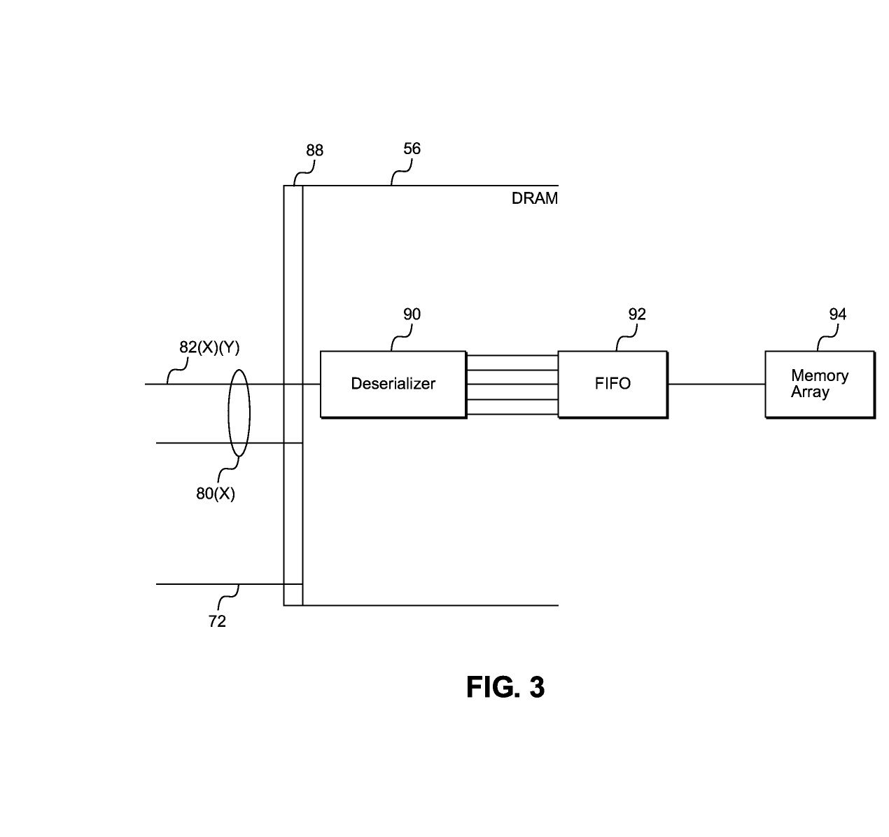

As described above, the conventional DRAM elements 16 and 18 of FIG. 1 expect to receive parallel data bits for each word sent from the SoC 12. Accordingly, changes are made in the DRAM elements 56 and 58 of FIG. 2 to capture the serialized data sent from the SoC 52. In this regard, FIG. 3 illustrates a block diagram of a DRAM element 56 with the understanding that the DRAM element 58 is similar. In particular, a data lane 82(X)(Y) of the M lane bus 80(X) is coupled to a DRAM bus interface 88 of the DRAM element 56. Serialized data is passed from the DRAM bus interface 88 to a deserializer 90, which deserializes the data into parallel data. The deserialized (parallel) data is passed from the deserializer 90 to a first in first out (FIFO) buffer 92, which in turn uploads the word into a memory array 94 as is well understood. In an exemplary aspect, the size of the FIFO buffer 92 is the same as the memory access length (MAL). It should be appreciated that the DRAM bus interface 88 may not only be coupled to the data lane 82(X)(Y) but may also be coupled to all of the data lanes 82(1)(1)-82(1)(M) through 82(N)(1)-82(N)(M) of the M lane buses 80(1)-80(N) to receive data, and may be coupled to the communication lane 72 to receive the clock signal 64 (not illustrated) and/or the CA signals 70 (not illustrated). In an exemplary aspect, the communication lane 72 may be replaced by a dedicated command lane and a dedicated clock lane. In either case, it should be appreciated that clock signal 64 is a high speed clock signal.

By changing the data received at the DRAM elements 56 and 58 to serial data based on the clock signal 64 and then collecting the data in the FIFO buffer 92, the memory system 50 is able to eliminate the need for write leveling. That is, because the data arrives serially, there is no longer any requirement that the different parallel bits arrive at the same time, so the complicated procedures (e.g., write leveling) used to achieve such simultaneous arrival are not needed. Furthermore, aspects of the present disclosure also provide an adjustable bandwidth with commensurate power saving benefits without having to scale the frequency of the bus. Specifically, unused lanes may be turned off if the unused lanes are not needed. The dynamic bandwidth is effectuated by turning off lanes when lower bandwidth is possible and reactivating lanes when more bandwidth is required. In contrast, conventional memory systems, such as the memory system 10 of FIG. 1, can only achieve such dynamic bandwidth through clock frequency scaling. Because clock frequency scaling requires the entire clocking architecture (from the PLL to the clock distribution) to change frequency dynamically to save power, such clock frequency scaling is generally expensive and consumes relatively large amounts of area within the memory system. Enabling bandwidth scaling without frequency scaling enables power savings without the complications associated with dynamic frequency scaling. In addition, if further options for bandwidth scaling are needed, a divider (e.g., a by 2ⁿ which can be achieved by simple post dividers) of the clock signal 64 or other interesting options including selective lane activation can be used.

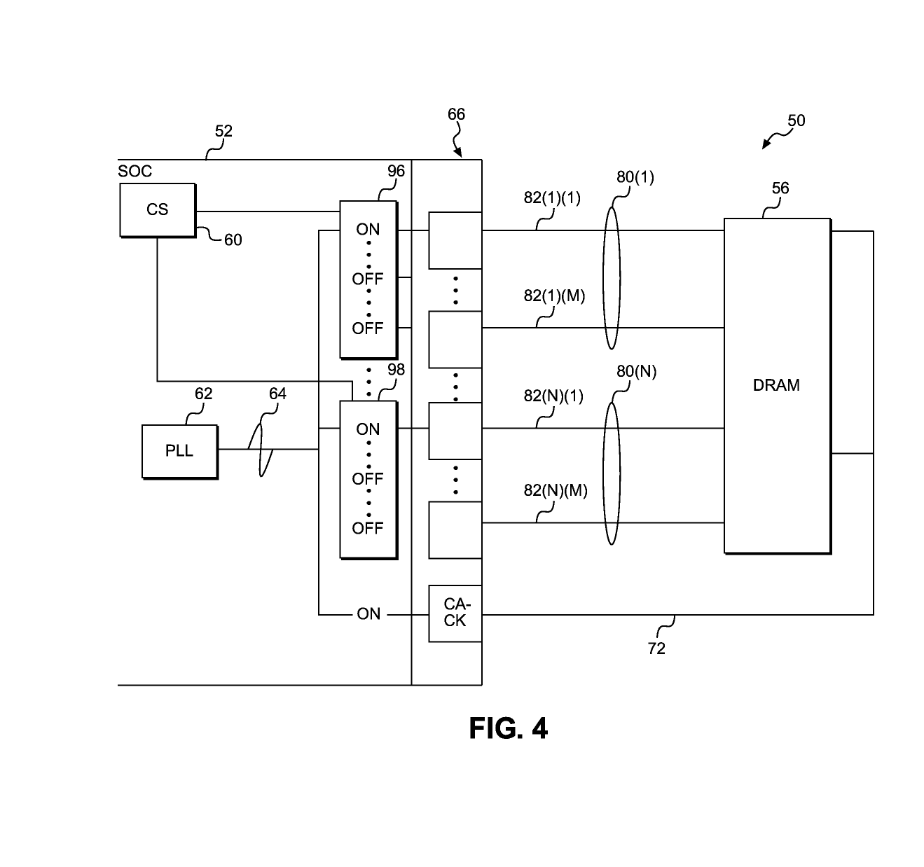

In this regard, FIG. 4 illustrates the memory system 50 of FIG. 2 with bandwidth and power scaling accomplished by using serial data transfers and selective lane activation. Note that for simplicity, some elements of the SoC 52 have been omitted. The SoC 52 includes a first switching element 96 for the first M lane bus 80(1) and corresponding additional switching elements for other M lane buses 80(2)-80(N), although only a second switching element 98 is illustrated for M lane bus 80(N). The first switching element 96 may have switches that allow the individual data lanes 82(1)(1)-82(1)(M) to be deactivated. Similarly, the second switching element 98 may have switches that allow the individual data lanes 82(N)(1)-82(N)(M) to be deactivated. The additional switching elements may have similar switches, and there may be similar switching elements for other M lane buses. The control system 60 may control the first and second switching elements 96 and 98. By activating and deactivating individual lanes, the effective bandwidth of the M lane bus 80 is changed. For example, by turning off half the data lanes 82(1)(1)-82(1)(M), the bandwidth of the M lane bus 80(1) is halved and the power consumption is halved. While illustrated and described as the first and second switching elements 96 and 98, it should be appreciated that such routing may be done through the multiplexer described above. Note that a given data lane 82 may include both binary data and/or coded symbols over a limited number of wires.

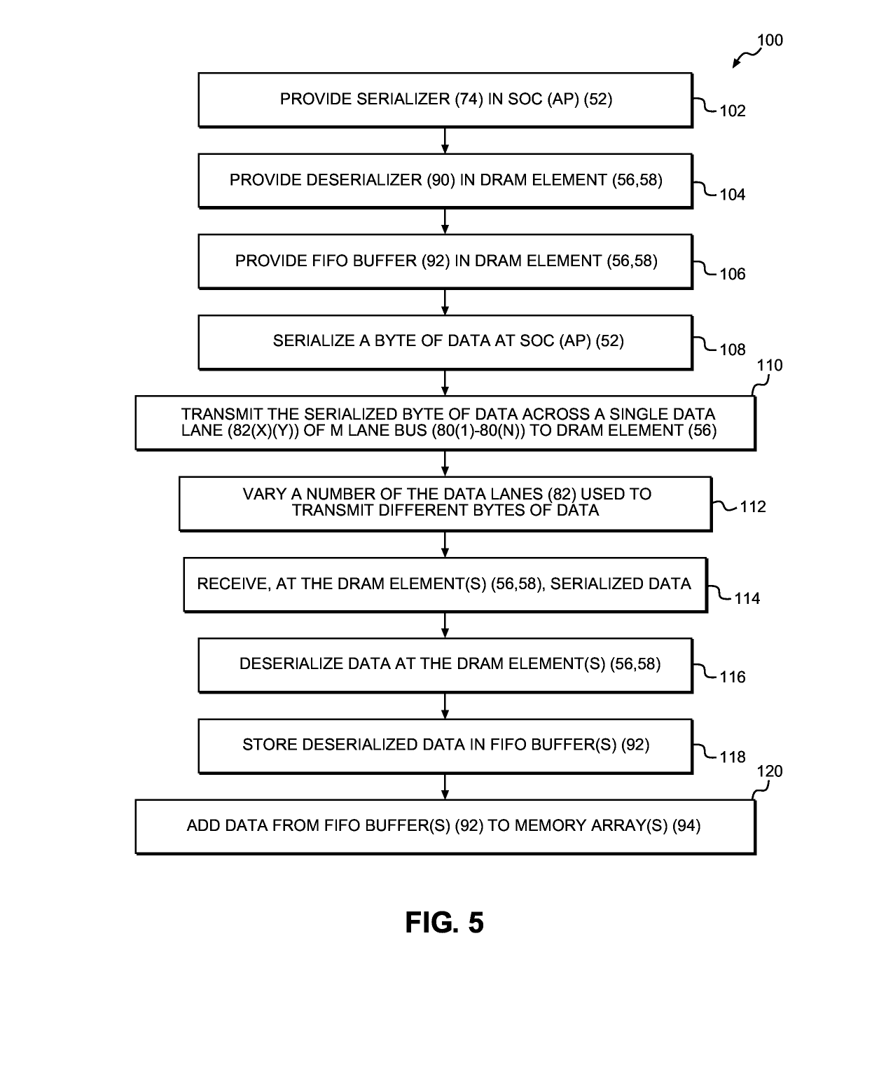

Against this backdrop of hardware, FIG. 5 illustrates a flowchart that illustrates a process 100 that may be used with the memory system 50 of FIG. 2 according to exemplary aspects of the present disclosure. The process 100 begins by providing the serializer 74 in the SoC (AP) 52 (block 102). The deserializer(s) 90 are provided in the DRAM elements 56 and 58 (block 104). In addition the deserializer(s) 90, the FIFO buffer(s) 92 are provided in the DRAM elements 56 and 58 (block 106).

With continued reference to FIG. 5, once the hardware is provided, data to be stored in the DRAM element(s) 56 (and 58) is generated. The data so generated is broken into words, each byte of which is serialized at the SoC (AP) 52 (block 108) by the serializer 74. The control system 60 determines which data lane is to be used to transmit the serialized data, and routes the serialized data to the appropriate data lane. Then the SoC 52 transmits the serialized byte of data across a single data lane (e.g., data lane 82(X)(Y)) of the M lane bus (e.g., M lane bus 80(1)-80(N)) to a DRAM element (e.g., the DRAM element 56) (block 110). Where plural bytes are being sent, the control system 60 may determine and vary a number of data lanes used to transmit different bytes of data (block 112).

With continued reference to FIG. 5, the process 100 continues by receiving, at the DRAM element(s) 56 and 58 the serialized data (block 114). The deserializer 90 then deserializes the data at the DRAM element(s) 56 and 58 (block 116). The deserialized data is stored in the FIFO buffer(s) 92 (block 118) and loaded from the FIFO buffer(s) 92 to the memory array(s) 94 (block 120).

As noted above, because the speed of the M lane bus 80 and M′ lane bus 84 is relatively high, the delay between arrival of the first bit of a byte and the last bit of a byte is relatively small. Thus, any latency introduced by the delay in deserializing and storing in the FIFO buffer 92 is acceptable when compared to the expense and difficulty associated with write leveling and/or using a variable frequency PLL.

The serial data transmission for DRAM interfaces according to aspects disclosed herein may be provided in or integrated into any processor-based device. Examples, without limitation, include a set top box, an entertainment unit, a navigation device, a communication device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

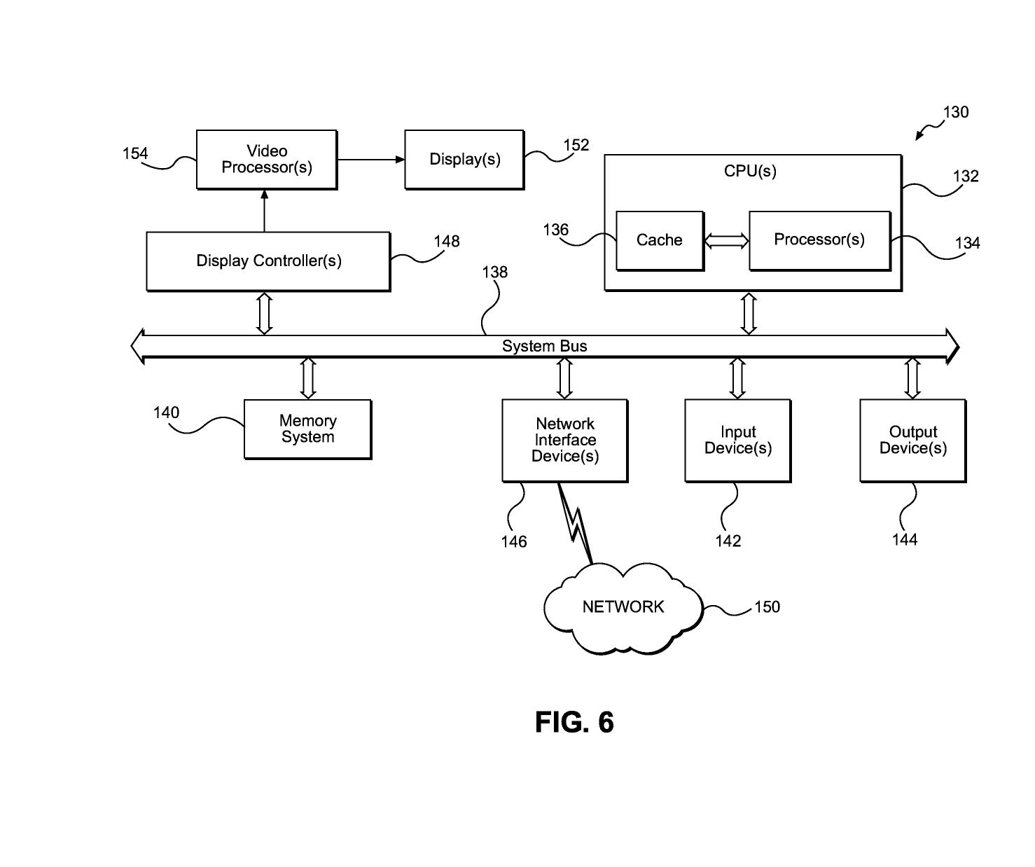

In this regard, FIG. 6 illustrates an example of a processor-based system 130 that can employ serial data transmission for the memory system 50 illustrated in FIG. 2. In this example, the processor-based system 130 includes one or more central processing units (CPUs) 132, each including one or more processors 134. The CPU(s) 132 may have cache memory 136 coupled to the processor(s) 134 for rapid access to temporarily stored data. The CPU(s) 132 is coupled to a system bus 138 and can intercouple devices included in the processor-based system 130. As is well known, the CPU(s) 132 communicates with these other devices by exchanging address, control, and data information over the system bus 138. Note that the system bus 138 may be buses 80, 84 of FIG. 2 or the M lane buses 80, 84 may be internal to the CPU 132.

Other devices can be connected to the system bus 138. As illustrated in FIG. 6, these devices can include a memory system 140, one or more input devices 142, one or more output devices 144, one or more network interface devices 146, and one or more display controllers 148, as examples. The input device(s) 142 can include any type of input device, including but not limited to input keys, switches, voice processors, etc. The output device(s) 144 can include any type of output device, including but not limited to audio, video, other visual indicators, etc. The network interface device(s) 146 can be any devices configured to allow exchange of data to and from a network 150. The network 150 can be any type of network, including but not limited to a wired or wireless network, a private or public network, a local area network (LAN), a wireless local area network (WLAN), a wide area network (WAN), a BLUETOOTH™ network, and the Internet. The network interface device(s) 146 can be configured to support any type of communication protocol desired.

The CPU(s) 132 may also be configured to access the display controller(s) 148 over the system bus 138 to control information sent to one or more displays 152. The display controller(s) 148 sends information to the display(s) 152 to be displayed via one or more video processors 154, which process the information to be displayed into a format suitable for the display(s) 152. The display(s) 152 can include any type of display, including but not limited to a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagram may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A method comprising:
serializing a byte of data at an applications processor (AP);
transmitting the serialized byte of data across a single lane of a bus to a dynamic random access memory (DRAM) element; and
receiving, at the DRAM element, the serialized byte of data from the single lane of the bus.

2. The method of claim 1, further comprising deserializing, at the DRAM element, the serialized byte of data.

3. The method of claim 2, further comprising storing the deserialized byte of data in a first in first out (FIFO) buffer.

4. The method of claim 1, further comprising loading data from the serialized byte of data into a memory array of the DRAM element.

5. The method of claim 1, further comprising serializing more than one other bytes of data at the AP; and
sending the more than one other byte of data over different lanes of the bus to the DRAM element.

6. The method of claim 5, further comprising varying a number of the different lanes used based on how many more than one other bytes of data are present.

7. A memory system comprising:
a communication bus comprising a plurality of data lanes and a command lane;
an applications processor (AP) comprising:
a serializer;
a bus interface operatively coupled to the communication bus; and
a control system configured to cause the serializer to serialize a byte of data and pass the serialized byte of data through the bus interface to the communication bus; and
a dynamic random access memory (DRAM) element comprising:
a DRAM bus interface operatively coupled to the communication bus;
a deserializer configured to receive data from the DRAM bus interface and deserialize the received data; and
a memory array configured to store data received by the DRAM element.

8. The memory system of claim 7, wherein the DRAM element further comprises a first in first out (FIFO) buffer configured to store the deserialized data before the deserialized data is loaded into the memory array.

9. The memory system of claim 7, wherein the communication bus further comprises a clock lane.

10. The memory system of claim 9, wherein the clock lane is the command lane.

11. The memory system of claim 7, wherein the control system is configured to send data on the plurality of data lanes and vary a number of data lanes used based on a calculated bandwidth required for the data to be sent to the DRAM element.

12. The memory system of claim 7, wherein the AP further comprises a phase locked loop to create a clock signal.

13. An applications processor (AP) comprising:
a serializer;
a bus interface operatively coupled to a communication bus; and
a control system configured to cause the serializer to serialize a byte of data and pass the serialized byte of data through the bus interface to a single lane of the communication bus.

14. The AP of claim 13, further comprising a phase locked loop to create a clock signal, the clock signal used by the bus interface.

15. The AP of claim 13, wherein the bus interface is configured to handle plural data lanes associated with the communication bus.

16. The AP of claim 15, wherein the bus interface is configured to couple to a communication lane configured to receive a clock signal and a command and address signal.

17. The AP of claim 16, wherein the communication lane is configured to carry both the clock signal and the command and address signal.

18. The AP of claim 15, wherein the control system is configured to turn lanes on and off within the plural data lanes.

19. A dynamic random access memory (DRAM) element comprising:
a DRAM bus interface operatively coupled to a communication bus;
a deserializer configured to receive data from the DRAM bus interface and deserialize the received data; and
a memory array configured to store the data received by the DRAM element.

20. The DRAM element of claim 19, wherein the DRAM bus interface is configured to receive plural data lanes from the communication bus.

21. The DRAM element of claim 20, wherein one of the plural data lanes comprises a clock lane.

22. The DRAM element of claim 20, wherein one of the plural data lanes comprises a command lane.

23. The DRAM element of claim 19, further comprising a first in first out (FIFO) buffer connected to the deserializer and configured to receive the deserialized data from the deserializer.

24. The DRAM element of claim 23, wherein the FIFO buffer is further configured to load data to the memory array.
